(19) United States
(12) Patent Application Publication
(10) Pub. No.: US 2009/0140252 A1
(43) Pub. Date: Jun. 4, 2009

(54) IMAGE SENSOR AND METHOD FOR MANUFACTURING THE SENSOR

(76) Inventor: Chong-Hoon Shin, Siheung-si (KR)

Correspondence Address: SHERR & VAUGHN, PLLC, 620 HERNDON PARKWAY, SUITE 200, HERNDON, VA, 20170, US

(21) Appl. No.: 12/325,167

(22) Filed: Nov. 29, 2008

(30) Foreign Application Priority Data
Nov. 30, 2007 (KR) 10-2007-0123440

(51) Int. Cl. H01L 31/00; H01L 21/02; H01L 21/3205

(52) U.S. Cl. 257/59; 438/73; 438/591; 257/E31.11; 257/E21.002; 257/E21.49

(57) ABSTRACT

An image sensor and a method of manufacturing the sensor. A method of manufacturing an image sensor may include at least one of: Forming a gate over a semiconductor substrate. Sequentially depositing a plurality of insulating films over the semiconductor substrate and the gate. Removing an upper-most insulating film of the plurality of insulating films by dry etching, thus forming a spacer at sides of the gate. Removing other insulating films by wet etching, while maintaining a bottom-most insulating film of the plurality of insulating films over the semiconductor substrate. Attacks may be prevented on a surface of a semiconductor substrate, making it possible to reduce generation of a dark signal, prevent plasma damage by controlling the thickness of a remaining oxide film with ease, and making it possible to improve yield and resolution of an image.

The present application claims priority under 35 U.S.C. 119 to Korean Patent Application No. 10-2007-0123440 (filed on Nov. 30, 2007), which is hereby incorporated by reference in its entirety.

### BACKGROUND

CMOS Image Sensors (CIS) may have various kinds of failures. For example, a dark signal may be generated during a Front End Of the Line (FEOL) process. One reason for dark signal generation is due to silicon attack. For example, an etching process and implant process performed during manufacturing of an image sensor may cause damage to a surface of a silicon substrate. The surface of the semiconductor substrate damaged by an implant process may be treated through an annealing process. However, a surface of a semiconductor substrate damaged by over-etching may not be easily treated. A pixel unit and a peripheral circuit unit of an image sensor are different from each other and may need to be etched under different conditions.

Example FIG. 1 illustrates a gate and a spacer of an image sensor. Spacer 20 may be formed on and/or sides of gate 13 by forming a plurality of insulating films 14, 16 and 18 on and/or over semiconductor substrate 10 and gate 13. The plurality of insulating films 14, 16 and 18 may then be etched back (e.g. by Reactive Ion Etching (RIE)) to form the spacer 20. During an etch back process, the silicon surface of semiconductor substrate 10 may be compromised. For example, silicon surface 22 of semiconductor substrate 10 may be damaged at a depth of about 150 Å to about 200 Å. It may be relatively difficult to control etching at resolutions less than 200 Å in reactive ion etching. Accordingly, semiconductor substrate 10 may be compromised, which may result in semiconductor substrate 10 being lowered to be a source of a dark signal.

### SUMMARY

Embodiments relates an image sensor (and method of manufacturing an image sensor) that substantially prevents and/or minimizes occurrence of dark signals due to a damaged semiconductor substrate. In embodiments, an image sensor may have substantially no damage and/or minimal damage to a surface of a semiconductor substrate when a spacer is formed on sides of a gate.

In embodiments, a method of manufacturing an image sensor includes at least one of the following steps: Forming a gate on a semiconductor substrate. Sequentially depositing a plurality of insulating films on and/or over the semiconductor substrate and the gate. Removing at least a portion of an upper-most insulating film from the plurality of insulating films (e.g. by dry etching). Removing other insulating films (e.g. by wet etching), while maintaining a bottom-most insulating film from of the plurality of insulating films.

In embodiments, a method of manufacturing an image sensor comprises at least one of the following steps: Forming a gate on and/or over a semiconductor substrate. Depositing a first insulating film on and/or over the semiconductor substrate and the gate. Depositing a second insulating film on and/or over the first insulating film. Forming a spacer on sides of the gate by dry etching the second insulating film and removing the second insulating film by wet etching, while maintaining the first insulating film on and/or over the semiconductor substrate.

In embodiments, an image sensor comprises at least one of: A gate formed on and/or over a semiconductor substrate. A multilayer spacer formed on and/or over sides of the gate. An insulating film formed over the semiconductor substrate in contact with an upper-most layer of the multilayer spacer.

### DRAWINGS

FIG. 1 illustrates a gate and a spacer in an image sensor.

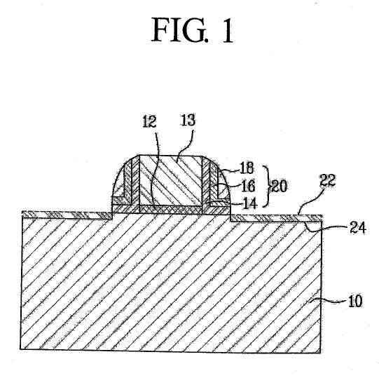

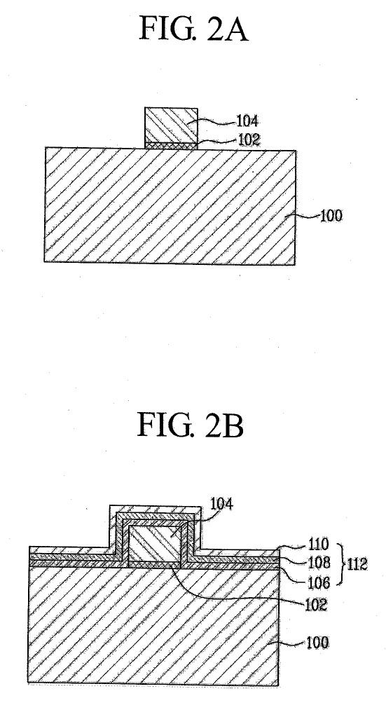

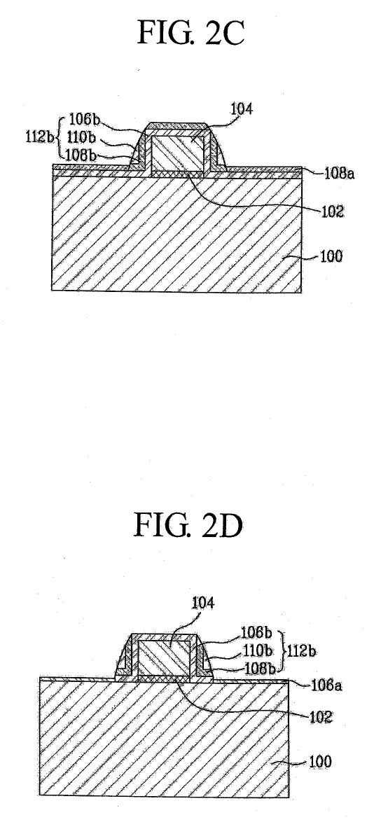

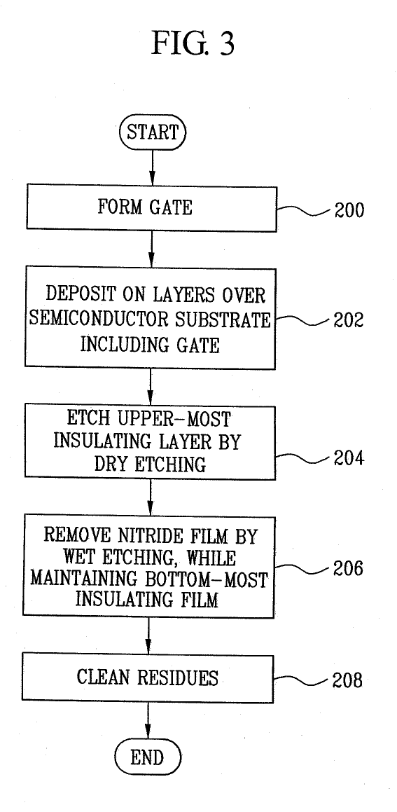

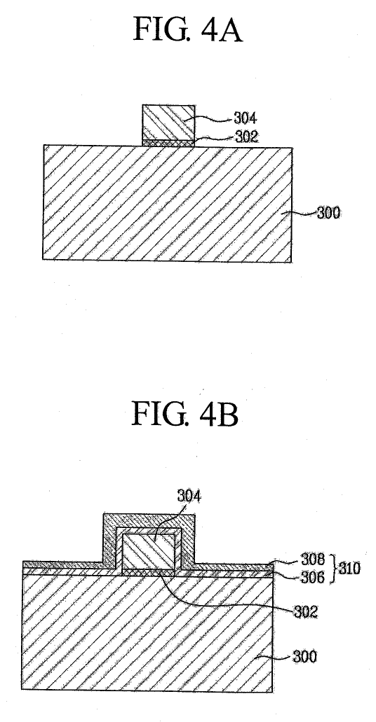

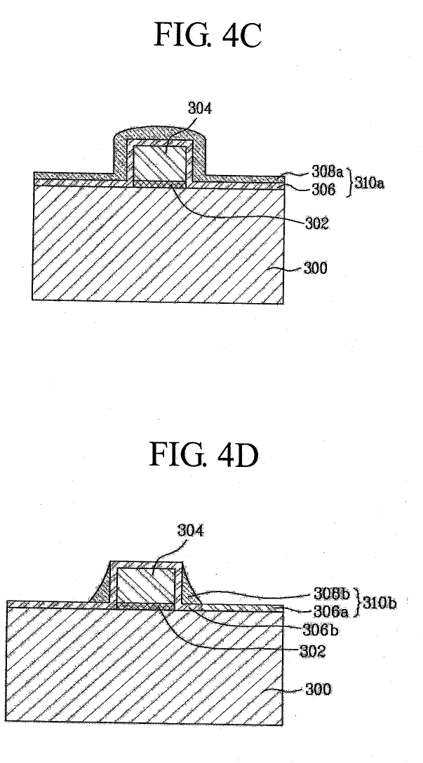

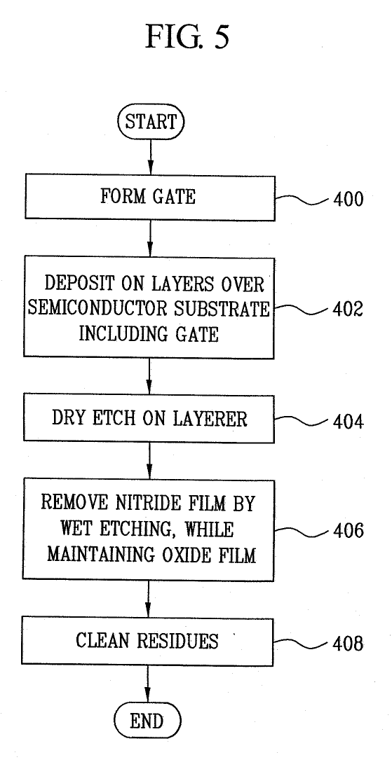

Example FIGS. 2A to 2D illustrate cross-sectional views illustrating a method of manufacturing an image sensor, in accordance with embodiments.

Example FIG. 3 illustrates a flowchart illustrating a method of manufacturing an image sensor, in accordance with embodiments.

Example FIGS. 4A to 4D illustrate a method of manufacturing an image sensor, in accordance with embodiments.

Example FIG. 5 illustrates a flowchart illustrating a method of manufacturing an image sensor, in accordance with embodiments.

### DESCRIPTION

An image sensor may include a pixel unit and a peripheral circuit unit. A pixel unit may be configured to sense light and generate a signal. A peripheral circuit unit may be configured to process a signal from the pixel unit. A pixel unit may include a receiving device that senses light. A peripheral circuit unit may include a correlation double sampling unit configured to remove noise from an output signal of the pixel unit. A peripheral circuit unit may include an analog/digital converter configured to convert an analog signal into a digital signal. A receiving device of the pixel unit may use a photodiode and at least one MOS transistor may be formed in an active region connected to the receiving device.

A semiconductor substrate may include an active region and a device isolation region. A device isolation film may be formed in the device isolation region through a Shallow Trench Isolation (STI) process. In accordance with embodiments, an image sensor may include a gate and a spacer.

Example FIGS. 2A to 2D are cross-sectional views illustrating a method of manufacturing an image sensor, in accordance with embodiments. Example FIG. 3 illustrates a flowchart illustrating a method of manufacturing an image sensor, in accordance with embodiments.

As illustrated in example FIG. 2A, gate oxide film 102 and gate 104 may be formed on and/or over semiconductor substrate 100 (e.g. Step 200), in accordance with embodiments. Step 200 may be performed after a device isolation film defining an active region and a device isolation region is formed in the device isolation region of the semiconductor substrate. In step 200, an oxide film and/or polysilicon may be deposited over the semiconductor substrate 100. The oxide film and/or polysilicon may be patterned to form gate oxide film 102 and gate 104.

As illustrated in example FIG. 2B, a plurality of insulating films may be sequentially deposited on and/or over semiconductor substrate 100 and gate 104 (e.g. Step 202), in accordance with embodiments. For example, a plurality of insulating films may be a three-layer film having an Oxide-Nitride-Oxide (ONO) structure. In embodiments, a plurality of insulating films may include a bottom-most insulating film may be first oxide film 106, an upper-most insulating film may be second oxide film 110, and nitride film 108 between the first oxide film 106 and the second oxide film 110.

As illustrated in example FIG. 2C, upper-most insulating film 110 may be removed by dry etching (e.g. Step 204) to form spacer 112b, in accordance with embodiments. Spacer 112b may be formed on sides of gate 104 and gate oxide film 102. Spacer 112b may include the dry etched upper-most insulating film 110b, the nitride film 108b and the bottom-most insulating film 106b. A portion of nitride film 108 formed over semiconductor substrate 100 that is to the sides of spacer 112b, may be partially etched. For example, the thickness of the partially etched nitride film 108a may be approximately 100 Å, in accordance with embodiments. In embodiments, the thickness of nitride film 108a may be less than the thickness of the nitride film 108b formed in spacer 112b.

As illustrated in example FIG. 2D, at least a portion of bottom-most insulating layer 106a remains over the semiconductor substrate 100, in accordance with embodiments. In embodiments, nitride film 108a and other insulating films may be removed (e.g. by wet etching) (e.g. Step 206). In embodiments, after wet etching, at least a portion of bottom-most insulating film 106b may remain on and/or over an upper surface of gate 104. In embodiments, nitride film 108a may be removed by wet etching and residue from generated nitride is cleaned (e.g. Step 208).

Example FIGS. 4A to 4D are cross-sectional views illustrating a method of manufacturing an image sensor, in accordance with embodiments. Example FIG. 5 is a flowchart illustrating a method of manufacturing an image sensor, in accordance with embodiments.

As illustrated in example FIG. 4A, gate oxide film 302 and gate 304 may be formed on and/or over semiconductor substrate 300 (e.g. Step 402), in accordance with embodiments. As illustrated in example FIG. 4B, first insulating film 306 and second insulating film 308 (e.g. collectively insulating films 310) may be sequentially deposited on and/or over semiconductor substrate 300 and/or gate 304 (e.g. Step 402). In embodiments, first insulating film 306 may be an oxide film and/or second insulating film 308 may be a nitride film. In embodiments, insulating films 310 maybe Oxide-Nitride (ON) layers.

As illustrated in example FIG. 4C, spacer 310a may be formed at the sides of gate oxide film 302 and gate 304 by dry etching second insulating film 308 to form nitride film 308a (e.g. Step 404), in accordance with embodiments. The spacer 310a may include oxide film 306 and dry etched nitride film 308a. As illustrated in example FIG. 4D, at least a portion of first insulating film 306 may remain on and/or over semiconductor substrate 300, while second insulating film 308a is removed (e.g. by wet etching) (e.g. Step 406). While removing second insulating film 308a by wet etching, a portion of the second insulating film 308a included in the spacer 310a may also be removed, in accordance with embodiments. In embodiments, a formed spacer 310b may include at least a portion of nitride film 308b (e.g. which is not wet etched) and oxide film 306a. In embodiments, residue from nitride film 308a may be cleaned from oxide film 306a (e.g. Step 408). In embodiments, a photodiode region may be formed to the side of spacer 112b and/or spacer 310b (e.g. by ion implantation). Gate 104, gate 304, spacer 112b, and/or spacer 310b may be used as an ion implantation mask. In embodiments, dry etching performed in step 202 and/or step 402 may be ion etching.

In embodiments, wet etching may be performed using phosphoric acid (H₃PO₄) solution or hydrofluoric acid (HF) as etching solution (e.g. in step 206 and/or step 406). A phosphoric acid solution may have an approximately 1:40 selectivity between the oxide film and the nitride film. Accordingly, in embodiments, the phosphoric acid solution may allow oxide film 106a and/or 306a and may also control the thickness of the remaining oxide film 106a and/or 306a. The concentration of a phosphoric acid may be between approximately 50% and approximately 90% (e.g. 85%). The processing condition of the wet etching may include a processing temperature between approximately 120° C. and approximately 160° C., in accordance with embodiments. In embodiments, a processing time may be between approximately 200 seconds and approximately 300 seconds. In embodiments, a batch type processing device may be used. One of ordinary skill in the art would appreciate that the processing time may be altered depending on the processing temperature. In embodiments, after step 206 and/or step 406 is performed, the thickness of oxide film 106a and/or 306a remaining on and/or over semiconductor substrate 100 and/or 300 may be between approximately 100 Å and approximately 200 Å.

In accordance with embodiments, as gate oxide film 102 and gate 104 may be formed on and/or over semiconductor substrate 100, as illustrated in example FIG. 2D. A multilayer spacer 112b may be formed on sides of gate 104 and oxide film 102. In embodiments, multilayer spacer 112b may have an ONO structure (i.e. oxide-nitride-oxide structure). In embodiments, insulating film 106a may be formed over semiconductor substrate 100, but not over gate 104 and spacer 112b. The insulating film 106a may be connected to a bottom-most layer of the multilayer spacer 112b. As illustrated in example FIG. 2D, the thickness of insulating film 106a may be smaller than that of the bottom-most layer 106b of the multilayer spacer 112b. In embodiments, insulating film 106a may be the oxide film and multilayer spacer 112b may include first oxide film 106b, nitride film 108b, and second oxide film 110b.

In accordance with embodiments, gate oxide 302 and a gate 304 may be formed on and/or over a semiconductor substrate 300, as illustrated in example FIG. 4D. A multilayer spacer 310b may be formed on sides of gate 304 and oxide film 302. In embodiments, multilayer spacer 310b may have an ON structure (i.e. oxide-nitride structure). In embodiments, insulating film 306a may be formed over semiconductor substrate 300, but not over gate 304 and spacer 310b. The insulating film 306a may be connected to a bottom-most layer of the multilayer spacer 310b. As illustrated in example FIG. 4D, the thickness of insulating film 306a may be smaller than that of the bottom-most layer 306b of the multilayer spacer 310b. In embodiments, insulating film 306b may be the oxide film and multilayer spacer 310b may include first oxide film 306b and the nitride film 308b.

As illustrated in example FIG. 4D, wet etching may maintain at least a portion of oxide film 306a and remove nitride film 308a, in accordance with embodiments. Further, in embodiments, a portion of nitride film 308b may be etched from spacer 310b. As illustrated in example FIG. 2D, wet etching may maintain at least a portion of oxide film 106a and remove nitride film 108a, with nitride film 108b being masked by oxide film 110b so that spacer 112b is not etched or is substantially unetched. Accordingly, an image sensor illustrated in example FIG. 2D may have a spacer with a more rounded shape compared to an image sensor illustrated in example FIG. 4D, in accordance with embodiments.

In embodiments, a of manufacturing a sensor may include a wet etching process to removing a nitride film, while maintaining at least a portion of an oxide film to the sides of a spacer. Embodiments may minimize and/or substantially prevent an attack on a surface of a semiconductor substrate. Embodiments may substantially prevent, prevent, and/or minimize generation of a dark signal. Embodiments may substantially prevent, prevent, and/or minimize plasma damage by controlling the thickness of a remaining oxide film. Embodiments may improve yield and/or resolution of an image.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method comprising:
forming a gate over a semiconductor substrate;
depositing a first insulating film over the semiconductor substrate and the gate;
depositing a second insulating film over the first insulating film;
depositing a third insulating film over the second insulating film;
removing a portion of the third insulating film by dry etching to form at least one spacer on sides of the gate; and
removing the second insulating film by wet etching, wherein said wet etching maintains at least a portion of the first insulating film over the semiconductor substrate.

2. The method of claim 1, wherein the method is a method of manufacturing an image sensor.

3. The method of claim 1, wherein:
the first insulating film is a first oxide film;
the second insulating film is a nitride film; and
the third insulating film is a second oxide film.

4. The method of claim 1, wherein the wet etching is performed using at least one of phosphoric acid and hydrofluoric acid as an etching solution.

5. The method of claim 4, wherein the etching solution is between approximately 50% and approximately 90% etching solution.

6. The method of claim 1, wherein the thickness of the first insulating film is between approximately 100 Å and approximately 200 Å after said wet etching.

7. The method of claim 1, comprising cleaning residue generated from the wet etching.

8. A method comprising:
forming a gate over a semiconductor substrate;
depositing a first insulating film over the semiconductor substrate and the gate;
depositing a second insulating films over the first insulating film;
forming a spacer on sides of the gate by dry etching the second insulating film;
removing at least a portion of the second insulating film by wet etching, wherein the wet etching maintains at least a portion of the first insulating film over the semiconductor substrate.

9. The method of claim 8, wherein the method is method of manufacturing an image sensor.

10. The method of claim 8, wherein:
the first insulating film is an oxide film; and
the second insulating film is a nitride film.

11. The method of claim 8, wherein the dry etching is reactive ion etching.

12. The method of claim 8, wherein the wet etching is performed using at least one of phosphoric acid and hydrofluoric acid as an etching solution.

13. The method of claim 12, wherein the etching solution is an between an approximately 50% and approximately 90% etching solution.

14. The method of claim 8, wherein the thickness of the first insulating film after said wet etching is between approximately 100 Å and approximately 200 Å.

15. The method of claim 8, comprising cleaning residue generated from the wet etching.

16. An image sensor comprising:
a gate formed over a semiconductor substrate;
a multilayer spacer formed at sides of the gate; and
an insulating film formed over the semiconductor substrate contiguous with the spacer and connected to an bottom-most layer of the multilayer spacer.

17. The image sensor of claim 16, wherein the thickness of the insulating film is less than the thickness of the bottom-most layer of the multilayer layer.

18. The image sensor of claim 16, wherein the insulating film is an oxide film.

19. The image sensor of claim 16, wherein the multilayer spacer comprises a first oxide film, a nitride film, and a second oxide film.

20. The image sensor of claim 16, wherein the multilayer spacer comprises a first oxide film and a nitride film.
